(19) United States
(12) Patent Application Publication
(10) Pub. No.: US 2026/0344126 A1
(43) Pub. Date: Oct. 29, 2026

(54) OPTOELECTRONIC DEVICE

(71) Applicant: ENNOSTAR CORPORATION, Hsinchu City (TW)

(72) Inventors: Meng-Hsiang HONG, Hsinchu City (TW); Chao-Hsing Chen, Hsinchu City (TW); Jhen-Yu Yang, Kaohsiung City (TW); Chi-Hsiang Yeh, Hsinchu City (TW)

(21) Appl. No.: 19/468,365

(22) Filed: Feb. 3, 2026

(30) Foreign Application Priority Data
Feb. 4, 2025 (TW) 114103953

(51) Int. Cl. H10H 20/841; H01S 5/028; H01S 5/042; H10F 77/20; H10F 77/30; H10H 20/831

(52) U.S. Cl. CPC H10H 20/841; H01S 5/028; H01S 5/04254; H10F 77/206; H10F 77/211; H10F 77/306; H10F 77/311; H10H 20/8314

(57) ABSTRACT

An optoelectronic device includes: a first semiconductor structure; a semiconductor mesa disposed on the first semiconductor structure and including an active structure and a second semiconductor structure, the semiconductor mesa comprising a first boundary with a length; and an insulating reflective structure including a first insulating reflective structure opening disposed on the second semiconductor structure. In a top view of the optoelectronic device, the first insulating reflective structure opening comprises an annular opening disposed along the first boundary of the semiconductor mesa, the first insulating reflective structure opening has a first length along the first boundary, and a ratio between the first length and the length of the first boundary is greater than 0.8.

### CROSS-REFERENCE TO RELATED DISCLOSURES

This disclosure claims the right of priority of TW Disclosure No. 114103953 filed on Feb. 4, 2025, and the content of which is hereby incorporated by reference in its entirety.

### BACKGROUND

### Technical Field

The present disclosure relates to an optoelectronic device, and more particularly to a flip-chip optoelectronic device including a metal reflective structure and an insulating reflective structure.

A semiconductor device includes compound semiconductors composed of group III-V elements, such as gallium phosphide (GaP), gallium arsenide (GaAs), gallium nitride (GaN), and aluminum nitride (AlN). The semiconductor device may be a semiconductor optoelectronic device, such as a light-emitting diode (LED), lasers, a light detector, a solar cell, power devices, or acoustic wave devices. For example, LED is a solid-state semiconductor light-emitting device including advantages such as low power consumption, low heat generation, long operating lifetime, shock resistance, small size, fast response, and favorable optoelectronic characteristics, for example, a stable emission wavelength. Therefore, LED is widely applied in household appliances, equipment indicator lights, and optoelectronic products.

### SUMMARY

An optoelectronic device includes: a first semiconductor structure; a semiconductor mesa disposed on the first semiconductor structure and including an active structure and a second semiconductor structure, the semiconductor mesa comprising a first boundary with a length; and an insulating reflective structure comprising a first insulating reflective structure opening disposed on the second semiconductor structure. In a top view of the optoelectronic device, the first insulating reflective structure opening comprises an annular opening disposed along the first boundary of the semiconductor mesa, the first insulating reflective structure opening has a first length along the first boundary, and a ratio between the first length and the length of the first boundary is greater than 0.8.

### BRIEF DESCRIPTION OF THE DRAWINGS

The embodiments of the disclosure will be described in detail below with reference to the accompanying drawings. It should be noted that various features are not drawn to scale and are for illustrative purposes only. In fact, the dimensions of the elements may be enlarged or reduced to clearly demonstrate the technical features of the embodiments of the present disclosure.

FIG. 1 is a top view of an optoelectronic device 1 according to some embodiments of the present disclosure.

FIG. 2 is a cross-sectional view taken along line L-L′ of FIG. 1.

FIG. 3 is a partially enlarged view of region W1 of FIG. 1.

FIG. 4 is a partially enlarged view of region W2 of FIG. 1.

FIGS. 5A and 5B are cross-sectional views taken along line X-X′ of FIG. 1 according to some embodiments of the present disclosure.

FIGS. 6A and 6B are cross-sectional views taken along line Y-Y′ of FIG. 1 according to some embodiments of the present disclosure.

FIG. 7 is a schematic diagram of a light-emitting device 2 according to some embodiments of the present disclosure.

FIG. 8 is a schematic diagram of a backlight module 4 according to some embodiments of the present disclosure.

FIG. 9 is a schematic diagram of a display 5 according to some embodiments of the present disclosure.

FIG. 10 is a schematic diagram of a light-emitting device 6 according to some embodiments of the present disclosure.

FIG. 11 is a schematic diagram of a light-emitting device 7 according to some embodiments of the present disclosure.

### DETAILED DESCRIPTION OF THE EMBODIMENTS

The following disclosure provides many different embodiments for implementing different features of the present disclosure. The following disclosure describes specific examples of each element and its arrangement to simplify the explanation. Of course, these specific examples are not limiting. For example, if the embodiment of the present disclosure describes that a first feature is formed on or above a second feature, it means that the first feature and the second feature are in direct contact, or additional features are formed between the first feature and the second feature such that the first feature and the second feature may not be in direct contact.

It should be understood that other operating steps may be performed before, between or after the method, and in other embodiments of the method, part of the operating steps may be replaced or omitted.

In addition, space-related words may be used, such as “under”, “below”, “lower”, “above”, “on”, “higher” and the related, these spatially related terms are used to facilitate the description of the relationship between one element or feature(s) and another element or feature(s) in the illustrations. These spatially related terms include the various orientations of the device in use or operation, and the orientation depicted in the drawings. When the device is rotated to different orientations (rotated 45 degrees or at any other orientation), the spatially relative adjectives used in the device will be interpreted in accordance with the rotated orientation. Furthermore, when it is said that a first material layer is located on or above a second material layer, it includes the situation where the first material layer and the second material layer are in direct contact, or there may be one or more other materials separated between them. In the case, there may not be direct contact between the first material layer and the second material layer. In some embodiments of the present disclosure, unless otherwise defined, terms related to joining and connecting, such as “connection” or “interconnection”, may mean that two structures are in direct contact, or may also mean that two structures are not in direct contact and there are other structures located between these two structures. And the terms about joining and connecting can also include the situation where both structures are movable or both structures are fixed.

It should be understood that, although the terms “first”, “second”, “third”, etc. are used herein to describe various elements, parts, regions, layers and/or sections, these elements, parts, regions, layers and/or segments should not be limited by these terms. These terms may only be used to distinguish one element, part, region, layer or section from another element, part, region, layer or section. Thus, a first element, part, region, layer or section discussed below could be termed a second element, part, region, layer or section without departing from the teachings of the present disclosure.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure. However, the embodiments set forth below are provided to illustrate the optoelectronic device of the present disclosure instead of limiting the present disclosure to the embodiments below. In addition, unless otherwise specified, the dimensions, materials, shapes, and relative arrangements of the constituent components described in the embodiments are not intended to limit the scope of the present disclosure and are provided merely for explanation. Moreover, the sizes or positional relationships of the elements shown in the drawings may be exaggerated for clarity of illustration. In the following description, for brevity, identical or similar components are denoted by the same terms and reference numerals.

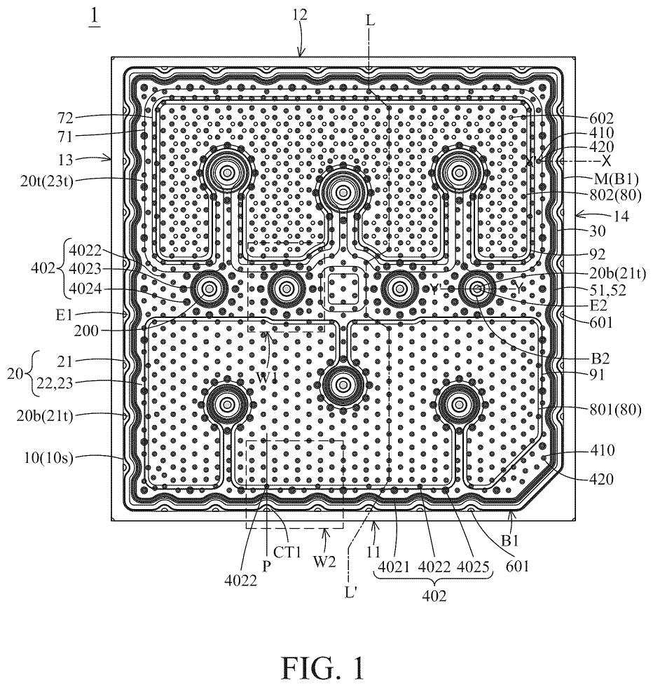

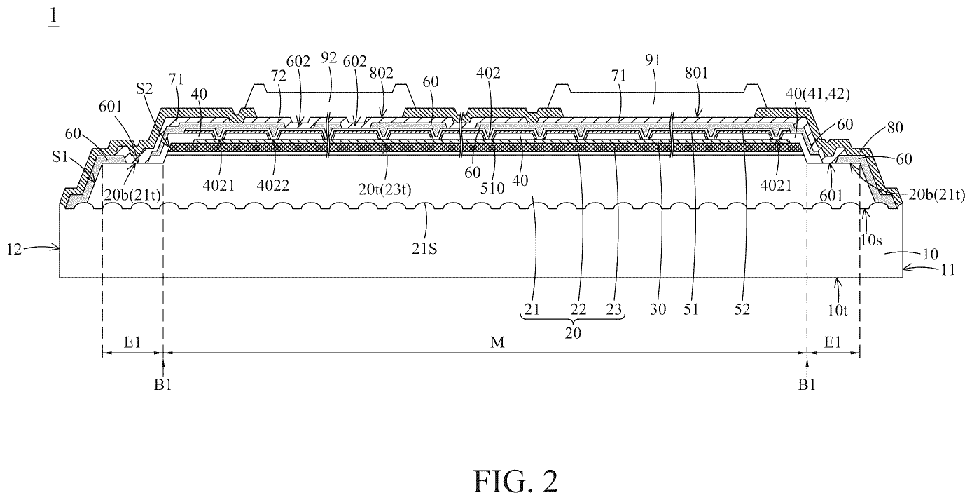

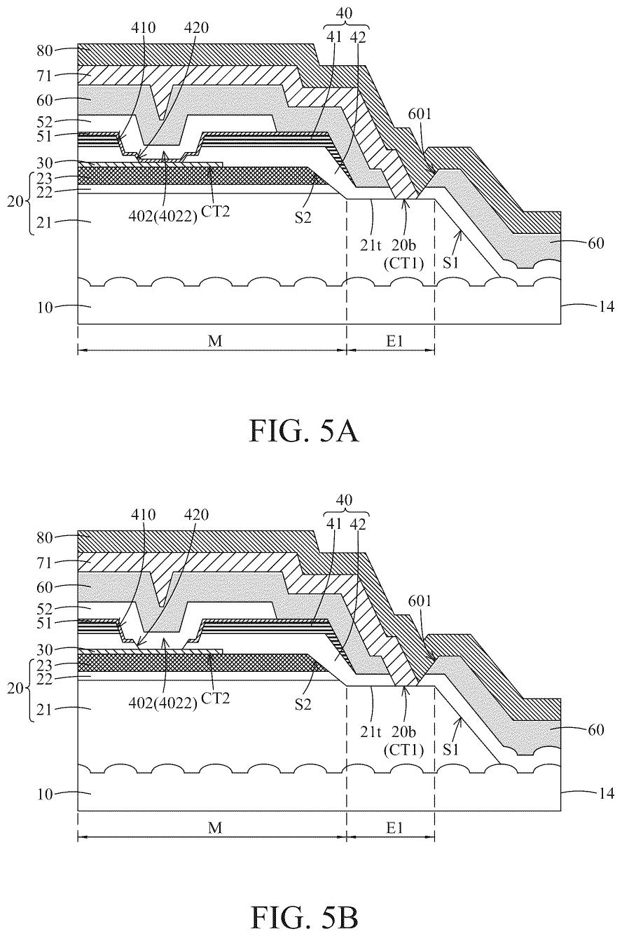

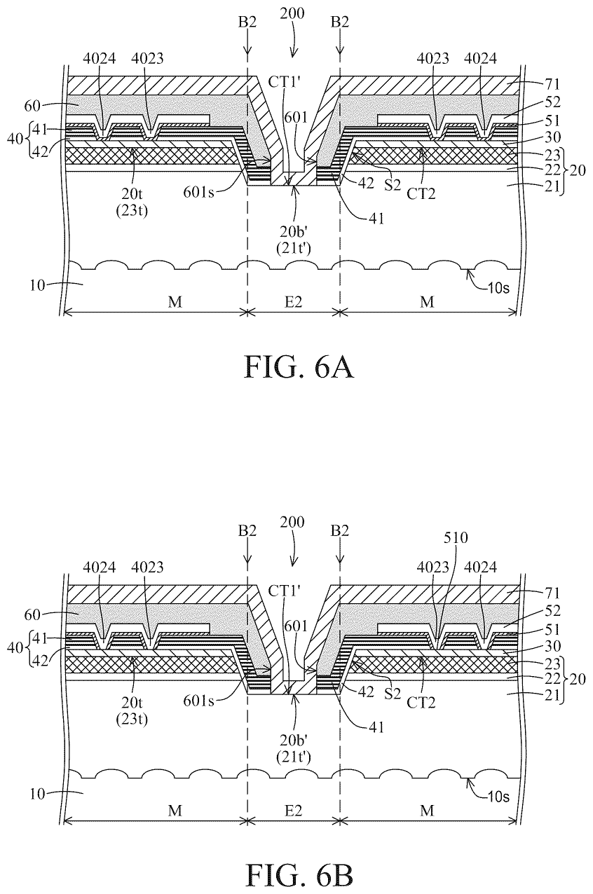

FIG. 1 is a top view of an optoelectronic device 1 according to some embodiments of the present disclosure. FIG. 2 is a cross-sectional view taken along line L-L′ of FIG. 1. FIGS. 5A and 5B are cross-sectional views taken along line X-X′ of FIG. 1. FIGS. 6A and 6B are cross-sectional views taken along line Y-Y′ of FIG. 1. The optoelectronic device 1 may include an electroluminescent light-emitting element, such as a light-emitting diode (LED) or a laser diode, or a photoelectric photovoltaic device, such as a solar cell or a photodetector.

Referring to FIGS. 1-2 and FIGS. 5A and 6A, in some embodiments, the optoelectronic device 1 includes a carrier substrate 10 having an upper surface 10s; a first semiconductor structure 21 disposed on the upper surface 10s of the carrier substrate 10 and having a first inclined surface S1 connected to the upper surface 10s of the carrier substrate 10; and a semiconductor mesa M disposed on the first semiconductor structure 21. The semiconductor mesa M includes an active structure 22 and a second semiconductor structure 23, and has a second inclined surface S2 connected to a first surface 21t of the first semiconductor structure 21.

Referring to FIGS. 1-2 and 5A-6B, the optoelectronic device 1 may optionally include a contact electrode 30 disposed on the second semiconductor structure 23. An insulating reflective structure 40 is disposed on the contact electrode 30 and includes one or a plurality of insulating reflective structure openings 402 disposed on the semiconductor mesa M or on the second semiconductor structure 23. In some embodiments, as shown in FIG. 2, the optoelectronic device 1 optionally includes an adhesive layer 51, and the adhesive layer 51 includes one or a plurality of adhesive layer openings 510 respectively corresponding to the one or plurality of insulating reflective structure openings 402. In another embodiment, the adhesive layer 51 continuously covers the insulating reflective structure 40 and does not include the one or a plurality of adhesive layer openings 510.

The optoelectronic device 1 includes a metal reflective structure 52 disposed on the adhesive layer 51 and filled into the one or plurality of insulating reflective structure openings 402. The metal reflective structure 52 forms an electrical connection to the contact electrode 30 and the second semiconductor structure 23 by covering the insulating reflective structure openings 402 and contacting the contact electrode 30.

The optoelectronic device 1 includes an insulating structure 60 disposed on the semiconductor mesa M, covering the metal reflective structure 52, the adhesive layer 51, and the insulating reflective structure 40. The insulating structure 60 includes one or a plurality of first insulating structure openings 601 located on the first semiconductor structure 21 and exposing the first semiconductor structure 21, and one or a plurality of second insulating structure openings 602 located on the metal reflective structure 52 and exposing the metal reflective structure 52.

The optoelectronic device 1 includes a first extension electrode 71 covering the semiconductor mesa M and form an electrical connection with the first semiconductor structure 21 through the first insulating structure openings 601. A second extension electrode 72 covers the semiconductor mesa M and the second insulating structure openings 602. The second extension electrode 72 forms an electrical connection with the metal reflective structure 52, the contact electrode 30, and the second semiconductor structure 23 through the second insulating structure openings 602. The optoelectronic device 1 includes a protecting structure 80 covering the first extension electrode 71 and the second extension electrode 72. The protecting structure 80 includes one or a plurality of first protecting structure openings 801 on the first extension electrode 71 and one or a plurality of second protecting structure openings 802 on the second extension electrode 72. One or a plurality of first electrode pads 91 respectively cover the first protecting structure openings 801 and form electrical connections to the first semiconductor structure 21 through the first extension electrode 71. One or a plurality of second electrode pads 92 respectively cover the second protecting structure openings 802 and form electrical connections to the second semiconductor structure 23 through the second extension electrode 72.

The carrier substrate 10 may be a growth substrate for epitaxially growing a semiconductor stack 20. In some embodiments, the carrier substrate 10 may be a bonding substrate including a bonding layer (not shown) located between the bonding substrate and the semiconductor stack 20. In some embodiments, the semiconductor stack 20 includes the first semiconductor structure 21, the active structure 22, and the second semiconductor structure 23. The carrier substrate 10 may include gallium arsenide (GaAs), sapphire (Al₂O₃), gallium nitride (GaN), silicon carbide (SiC), aluminum nitride (AlN), glass, or a circuit board.

In some embodiments of the present disclosure, the optoelectronic device 1 may be devoid of the carrier substrate 10. For example, the carrier substrate 10 may be a growth substrate used to form the semiconductor stack 20, and the carrier substrate 10 may thereafter be separated from the semiconductor stack 20 by laser lift-off (LLO), chemical lift-off, or the like.

In some embodiments of the present disclosure, the semiconductor stack 20 having optoelectronic characteristics may be formed on the carrier substrate 10 by metal-organic chemical vapor deposition (MOCVD), molecular beam epitaxy (MBE), hydride vapor phase epitaxy (HVPE), physical vapor deposition (PVD), or ion plating. The physical vapor deposition may include sputtering or evaporation.

By changing the physical and chemical composition of one or more layers of the semiconductor stack 20, the wavelength of light emitted or absorbed by the optoelectronic device 1 can be adjusted. In the case of a light-emitting device, the semiconductor stack 20 includes the first semiconductor structure 21, the active structure 22, and the second semiconductor structure 23, and the materials of the semiconductor stack 20 include Group III-V semiconductor materials. When the material of the semiconductor stack 20 is AlInGaP or InGaP, yellow, orange, or red light with a peak wavelength between 530 nm and 700 nm may be emitted. When the material of the semiconductor stack 20 is InGaN, blue light with a peak wavelength between 400 nm and 490 nm, green light with a peak wavelength between 530 nm and 550 nm, or red light with a peak wavelength between 560 nm and 650 nm may be emitted. When the material of the semiconductor stack 20 is AlGaN or AlInGaN, ultraviolet light with a peak wavelength between 250 nm and 400 nm may be emitted. When the materials of the semiconductor stack 20 include InGaAs, InGaAsP, AlGaAs, or AlGaInAs, infrared light with a peak wavelength between 700 nm and 1700 nm may be emitted.

The first semiconductor structure 21 and the second semiconductor structure 23 may be cladding layers or confinement layers with different conductivity types, electrical properties, polarities, or dopants for providing electrons or holes. For example, the first semiconductor structure 21 may be an n-type semiconductor and the second semiconductor structure 23 may be a p-type semiconductor. Alternatively, the first semiconductor structure 21 may be p-type and the second semiconductor structure 23 may be n-type. The active structure 22 is formed between the first semiconductor structure 21 and the second semiconductor structure 23. Under current injection, electrons and holes recombine in the active structure 22, converting electrical energy into optical energy to emit light, or converting optical energy into electrical energy to absorb light. The semiconductor stack 20 may be a single heterostructure (SH), a double heterostructure (DH), a double-side double heterostructure (DDH), or a multi-quantum well (MQW) structure. The material of the active structure 22 may be a i-type, p-type, or n-type semiconductor. The first semiconductor structure 21, the active structure 22, or the second semiconductor structure 23 may be a single layer or include multiple sublayers.

In some embodiments, the semiconductor stack 20 may further include a buffer structure (not shown) between the first semiconductor structure 21 and the carrier substrate 10 to release stress caused by lattice mismatch between the carrier substrate 10 and the semiconductor stack 20, thereby reducing dislocations and lattice defects and improving epitaxial quality. The buffer structure may be a single layer or include multiple sublayers. In some embodiments, aluminum nitride (AlN) may be selected as the buffer structure and formed between the semiconductor stack 20 and the carrier substrate 10 to improve the epitaxial quality of the semiconductor stack 20.

As shown in FIGS. 1-2 and 5A-6B, the semiconductor stack 20 optionally includes one or a plurality of first recessed regions E1 located outside the semiconductor mesa M and one or a plurality of second recessed regions E2 located within the semiconductor mesa M. In other words, the first recessed regions E1 and the second recessed regions E2 respectively expose the first surface 21t and the second surface 21t′ of the first semiconductor structure 21. In some embodiments, the second semiconductor structure 23 and the active structure 22 may be removed by etching, and portions of the first semiconductor structure 21 may be further removed to form the first recessed regions E1 and the second recessed regions E2. In a top view of the optoelectronic device 1, one or a plurality of first recessed regions E1 may be located along one or more sides between the semiconductor mesa M and the carrier substrate 10. In some embodiments, as shown in FIG. 1, the first recessed regions E1 are located between the semiconductor mesa M and multiple sides of the carrier substrate 10 (first side 11, second side 12, third side 13, and fourth side 14), and the plurality of first recessed regions E1 surround the semiconductor mesa M. The second recessed region E2 is located within and surrounded by the semiconductor mesa M.

In FIG. 2, the reference number “B1” denotes a first boundary B1 between the first recessed region E1 and the semiconductor mesa M. In FIGS. 6A-6B, the reference number “B2” denotes a second boundary B2 between the second recessed region E2 and the semiconductor mesa M. An upper surface 20t of the semiconductor mesa M (i.e., a second surface 23t of the second semiconductor structure 23) is higher than an upper surface 20b of the first recessed region E1 (i.e., the first surface 21t of the first semiconductor structure 21). In some embodiments, a width of the semiconductor mesa M may taper from the first semiconductor structure 21 toward the second semiconductor structure 23, and a trapezoidal shape in a side view of the optoelectronic device 1 may be formed. Accordingly, a side surface of the semiconductor mesa M may be an inclined surface, such as the second inclined surface S2 shown in FIG. 2.

As shown in FIG. 1, the carrier substrate 10 includes a first side 11, a second side 12, a third side 13, and a fourth side 14. The semiconductor mesa M may be spaced apart from the first side 11 through the fourth side 14 so as to expose the upper surface 10s of the carrier substrate 10 and the first surface 21t of the first semiconductor structure 21, and the first recessed regions E1 may be disposed between the semiconductor mesa M and any one side, two opposite sides, multiple sides, or all four sides of the first side 11 through the fourth side 14 of the carrier substrate 10. For example, the first recessed regions E1 may be disposed between the semiconductor mesa M and the first side 11 and between the semiconductor mesa M and the second side 12, or between the semiconductor mesa M and the third side 13 and between the semiconductor mesa M and the fourth side 14. The first side 11 and the second side 12 may be opposite to each other, and the third side 13 and the fourth side 14 may be opposite to each other. In some embodiments, when the number of second recessed regions E2 is plural, the plurality of second recessed regions E2 located within the semiconductor mesa M may be spaced apart from each other. The plurality of second recessed regions E2 may have elongated shapes or polygonal shapes such as rectangular, circular, or elliptical.

In some embodiments, as shown in FIGS. 5A-5B, a portion of the first surface 21t of the first recessed region E1 may serve as a first contact first portion CT1. As shown in FIGS. 6A-6B, a portion of an upper surface 20b′ of the second recessed region E2 may serve as a first contact second portion CT1′. For example, the first extension electrode 71 may contact the first semiconductor structure 21 through the first insulating structure openings 601 to form the first contact first portion CT1 and the first contact second portion CT1′. In some embodiments, at least a portion of the upper surface 20t of the semiconductor mesa M may be a second contact portion CT2. For example, the contact electrode 30 contacts the second semiconductor structure 23 to form the second contact portion CT2.

Referring to FIG. 1, the optoelectronic device 1 includes a plurality of through holes 200 formed through the second semiconductor structure 23 and the active structure 22 in the second recessed region E2 to expose the second surface 21t′ of the first semiconductor structure 21. The number of through holes 200 is plural, and the shapes thereof include, without limitation, circular, rectangular, or polygonal shapes such as hexagonal, and may be distributed with uniform or non-uniform spacing. In this embodiment, the shape of the through holes 200 is circular. After current is supplied to the optoelectronic device 1, an external current is electrically connected to the first semiconductor structure 21 through the first extension electrode 71 in the through holes 200. The plurality of uniformly distributed through holes 200 can improve current spreading capability and the uniformity of current distribution, and also increase the area of the first contact second portion CT1′ formed between the first extension electrode 71 and the first semiconductor structure 21, thereby reducing voltage and improving the light emission efficiency of the optoelectronic device 1.

The number and distribution of the through holes 200 may be designed according to the size of the optoelectronic device 1. The larger the size of the optoelectronic device 1 results in a greater required number of through holes 200.

As shown in FIG. 2, FIGS. 5A-5B, and FIGS. 6A-6B, the contact electrode 30 may be directly disposed on the second semiconductor structure 23. A region where the contact electrode 30 contacts the second semiconductor structure 23 forms the second contact portion CT2 and is electrically connected to the second semiconductor structure 23. The contact electrode 30 is used to spread an externally injected current and then inject the current into the second semiconductor structure 23 through an upper surface 20t (a second upper surface 23t of the second semiconductor structure 23) of the semiconductor mesa M.

In some embodiments, as shown in FIG. 1 and FIGS. 5A-5B, to improve the uniformity of current spreading of the optoelectronic device 1, the plurality of insulating reflective structure openings 402 include a first insulating reflective structure opening 4021 and a plurality of second insulating reflective structure openings 4022 exposing the contact electrode 30. The first insulating reflective structure opening 4021 is closer to the first recessed region E1 than the plurality of second insulating reflective structure openings 4022. In a top view of the optoelectronic device 1, the first insulating reflective structure opening 4021 includes an annular opening disposed along a first boundary B1 between the first recessed region E1 and the semiconductor mesa M. The first insulating reflective structure opening 4021 has a first length along the first boundary B1, and a ratio between the first length and a length of the first boundary B1 is greater than 0.8. In this embodiment, the annular opening is a closed ring. The first insulating reflective structure opening 4021 has a top-view area greater than a top-view area of each of the plurality of second insulating reflective structure openings 4022. The top-view area of the first insulating reflective structure opening 4021 may be smaller than a total top-view area of the plurality of second insulating reflective structure openings 4022. The plurality of second insulating reflective structure openings 4022 is not located between the first insulating reflective structure opening 4021 and the first recessed region E1.

In some embodiments, the plurality of insulating reflective structure openings 402 further include a plurality of third insulating reflective structure openings 4023. Each third insulating reflective structure opening 4023 is disposed along a second boundary B2 between the second recessed region E2 and the semiconductor mesa M, and each third insulating reflective structure opening 4023 includes an annular opening. In this embodiment, the annular opening is a closed ring.

The plurality of insulating reflective structure openings 402 further includes a plurality of fourth insulating reflective structure openings 4024 disposed along the second boundary B2, and the plurality of fourth insulating reflective structure openings 4024 are arranged in an annular ring to surround the third insulating reflective structure opening 4023. The third insulating reflective structure opening 4023 is closer to the second recessed region E2 than the plurality of fourth insulating reflective structure openings 4024.

In some embodiments, the third insulating reflective structure opening 4023 has a top-view area greater than or smaller than a top-view area of the fourth insulating reflective structure opening 4024.

In some embodiments, the plurality of insulating reflective structure openings 402 further include a plurality of fifth insulating reflective structure openings 4025 disposed along the first boundary B1. The first insulating reflective structure opening 4021 is closer to the first boundary B1 of the semiconductor mesa M than the plurality of fifth insulating reflective structure openings 4025. In some embodiments, the top-view area of each fifth insulating reflective structure opening 4025 is smaller than, greater than, or equal to the top-view area of the second insulating reflective structure openings 4022 or the fourth insulating reflective structure openings 4024.

As shown in FIGS. 1, 5A, and 6A, the first extension electrode 71 covers the semiconductor mesa M and the first recessed region E1 and the second recessed region E2, and respectively forms the first contact first portion CT1 and the first contact second portion CT1′ in the first recessed region E1 and the second recessed region E2. In a top view, the fifth insulating reflective structure openings 4025 are not located on a line P orthogonal to a side (e.g., the first side 11, second side 12, third side 13, and fourth side 14) of the optoelectronic device 1 and passing through the first contact first portion CT1 (e.g., line P1 in FIG. 1). A portion of the second insulating reflective structure openings 4022 are disposed on the line P.

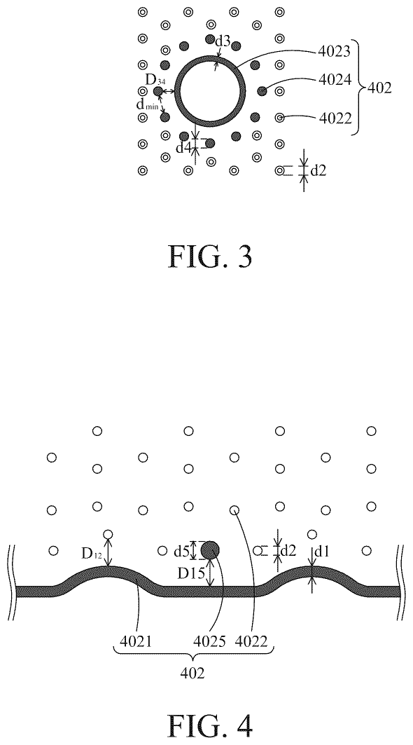

FIG. 3 is a partially enlarged view of region W1 of FIG. 1. FIG. 4 is a partially enlarged view of region W2 of FIG. 1. For convenience of description, FIGS. 3 and 4 only discloses the plurality of insulating reflective structure openings 402.

In some embodiments, as shown in FIGS. 1 and 3, the plurality of fourth insulating reflective structure openings 4024 are arranged annularly around the third insulating reflective structure opening 4023. The plurality of fourth insulating reflective structure openings 4024 surround the third insulating reflective structure opening 4023 and the through holes 200 at a minimum distance D34, and the plurality of fourth insulating reflective structure openings 4024 surrounding the through holes 200 are spaced apart from each other at an equal spacing with a minimum distance dₘᵢₙ. The minimum distance D34 between the third insulating reflective structure opening 4023 and the fourth insulating reflective structure openings 4024 is smaller than the minimum distance dₘᵢₙ between the plurality of fourth insulating reflective structure openings 4024. In this embodiment, a fourth width d4 of the fourth insulating reflective structure openings 4024 is greater than a third width d3 of the third insulating reflective structure opening 4023, and the third width d3 of the third insulating reflective structure opening 4023 is greater than a second width d2 of the second insulating reflective structure openings 4022.

In some embodiments, as shown in FIGS. 1 and 4, the plurality of fifth insulating reflective structure openings 4025 are arranged annularly around the first insulating reflective structure opening 4021. A minimum distance D15 is defined between the first insulating reflective structure opening 4021 and the fifth insulating reflective structure openings 4025. The plurality of fifth insulating reflective structure openings 4025 are spaced apart from each other by one or a plurality of second insulating reflective structure openings 4022, and a minimum distance D12 between the first insulating reflective structure opening 4021 and the second insulating reflective structure openings 4022 may be the same as the minimum distance D15 between the first insulating reflective structure opening 4021 and the fifth insulating reflective structure openings 4025. In this embodiment, a fifth width d5 of the fifth insulating reflective structure openings 4025 is greater than a first width d1 of the first insulating reflective structure opening 4021, and the first width d1 of the first insulating reflective structure opening 4021 is greater than the second width d2 of the second insulating reflective structure openings 4022.

As shown in FIG. 1, in a top view of the optoelectronic device 1, the second insulating reflective structure openings 4022, the fourth insulating reflective structure openings 4024, and the fifth insulating reflective structure openings 4025 may be circular, semicircular, elliptical, triangular, rectangular, polygonal, or arcuate. The plurality of second insulating reflective structure openings 4022 may be arranged on the semiconductor mesa M in a hexagonal close-packed pattern. In other embodiments, the plurality of second insulating reflective structure openings 4022 may be arranged in various patterns, such as a rectangular grid. As shown in FIGS. 5A-5B and 6A-6B, the insulating reflective structure 40 is disposed on the contact electrode 30 and covers the second inclined surface S2 of the semiconductor mesa M, and covers portions of the first semiconductor structure 21 and the second semiconductor structure 23. For example, the insulating reflective structure 40 may cover a portion of the first surface 21t and the second surface 21t′ of the first semiconductor structure 21 and a portion of the second upper surface 23t of the second semiconductor structure 23.

In some embodiments of the disclosure, as shown in FIGS. 2, 5A-5B, and 6A-6B, the insulating reflective structure 40 includes an insulating reflector 41 and/or an insulating layer 42. The insulating reflector 41 includes a first insulating reflective structure opening 410, and the insulating layer 42 includes a second insulating reflective structure opening 420. The first insulating reflective structure opening 410 and the second insulating reflective structure opening 420 may jointly form the insulating reflective structure openings 402 (e.g., the first opening 4021, the second openings 4022, the third opening 4023, the fourth openings 4024, and the fifth openings 4025). As shown in FIGS. 5A-5B and 6A-6B, the insulating reflector 41 of the insulating reflective structure 40 covers the second inclined surface S2 of the semiconductor mesa M to reflect light from the active structure 22 and increase the light extraction efficiency of the optoelectronic device 1.

In some embodiments of the disclosure, as shown in FIGS. 5A-5B and 6A-6B, the insulating layer 42 of the insulating reflective structure 40 is disposed between the contact electrode 30 and the insulating reflector 41. As shown in FIG. 1, in a top view of the optoelectronic device 1, the first insulating reflective structure opening 410 and the second insulating reflective structure opening 420 (e.g., the second openings 4022, the fourth openings 4024, and the fifth openings 4025) form a concentric pattern. The first insulating reflective structure opening 410 and the second insulating reflective structure opening 420 (e.g., the first opening 4021 and the third opening 4023) form an annular pattern.

As shown in FIGS. 5A-5B and 6A-6B, the adhesive layer 51 covers the insulating reflective structure 40 and is filled into the first insulating reflective structure openings 410 and the second insulating reflective structure openings 420 to contact the contact electrode 30. In some embodiments of the disclosure, the adhesive layer 51 has a thickness smaller than a thickness of the contact electrode 30. For example, the adhesive layer 51 has a thickness between 10 Å and 60 Å, and the contact electrode 30 has a thickness between 100 Å and 400 Å. In some embodiments, the contact electrode 30 and the adhesive layer 51 include the same material. For example, the contact electrode 30 and the adhesive layer 51 include indium tin oxide (ITO). In other embodiments, the contact electrode 30 and the adhesive layer 51 include different materials. For example, the contact electrode 30 includes indium tin oxide (ITO), and the adhesive layer 51 includes titanium (Ti).

The adhesive layer 51 can improve the adhesion between the insulating reflective structure 40 and the metal reflective structure 52. In some embodiments (not shown), when the adhesive layer 51 includes a conductive material and is filled into the insulating reflective structure openings 402 to contact the contact electrode 30 and/or the second semiconductor structure 23, the metal reflective structure 52 may be filled into the insulating reflective structure openings 402 of the insulating reflective structure 40 and form an electrical connection to the second semiconductor structure 23 through the adhesive layer 51. In other embodiments, as shown in FIGS. 5B and 6B, when the adhesive layer 51 includes a non-conductive material, the adhesive layer 51 includes adhesive layer openings 510 overlapping the insulating reflective structure openings 402, and the metal reflective structure 52 may be filled into the adhesive layer openings 510 to form an electrical connection to the second semiconductor structure 23.

In some embodiments, the adhesive layer 51 includes titanium (Ti), titanium oxide (TiOx), titanium nitride (TiNx), aluminum oxide (Al2O3), indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), or zinc magnesium oxide (Zn(1-x)MgxO, 0≤x≤1). The contact electrode 30 includes indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), or zinc magnesium oxide (Zn(1-x)MgxO, 0≤x≤1). The metal reflective structure 52 includes silver (Ag), chromium (Cr), nickel (Ni), titanium (Ti), aluminum (Al), rhodium (Rh), ruthenium (Ru), or combinations thereof.

In some embodiments, the optoelectronic device 1 includes a barrier layer (not shown) disposed on the metal reflective structure 52. The barrier layer may have a multilayer structure, for example, a multilayer stack in which Ti and Ni are alternately stacked.

The insulating reflective structure 40, the adhesive layer 51, and the metal reflective structure 52 can be configured as an omni-directional reflector (ODR). The omni-directional reflector can increase the reflectance of light emitted from the active structure 22, thereby improving the light extraction efficiency of the optoelectronic device 1.

In some embodiments, the insulating layer 42 of the insulating reflective structure 40 serves as an insulating film and has a single-layer structure that includes oxides or nitrides, for example, at least one oxide or nitride selected from the group consisting of metals such as silicon (Si), titanium (Ti), zirconium (Zr), niobium (Nb), tantalum (Ta), or aluminum (Al). In other embodiments, the insulating layer 42 may be a multilayer structure, for example, a stack including any two or more of the above oxides or nitrides, such as a multilayer structure formed of SiO₂, TiO₂, and Al₂O₃. In some embodiments, the insulating layer 42 may also be a distributed Bragg reflector (DBR).

In some embodiments, the insulating reflector 41 may be formed of a material having a refractive index lower than that of the second semiconductor structure 23. Materials for the insulating reflector 41 include SiO₂, SiN, SiOₓN_{y}, TiO₂, Si₃N₄, Al₂O₃, TiN, AlN, ZrO₂, TiAlN, TiSiN, HfO, TaO₂, Nb₂O₅, or MgF₂. In some embodiments, the insulating reflector 41 has a multilayer film structure alternately stacked by insulating sublayers including different refractive indices. The insulating reflector 41 may be a Distributed Bragg reflector (DBR). The Distributed Bragg reflector is formed by alternately stacking a plurality of first sublayers having a first refractive index and a plurality of second sublayers having a second refractive index. The first refractive index is smaller than the second refractive index. For example, a stack of SiO₂/TiO₂ or SiO₂/Nb₂O₅ may be implemented.

In some embodiments of the disclosure, when the insulating reflector 41 is a Distributed Bragg reflector formed of stacked SiO₂/TiO₂ or SiO₂/Nb₂O₅, the insulating layer 42 has a thickness greater than the thickness of each sublayer included in the insulating reflector 41 but smaller than a total thickness of the sublayers included in the insulating reflector 41. In some embodiments, the thickness of the insulating layer 42 is between 3000 Å and 7000 Å.

A bottommost layer or topmost layer of the insulating reflector 41 may be formed of at least one oxide or nitride selected from the group consisting of silicon (Si), titanium (Ti), zirconium (Zr), niobium (Nb), tantalum (Ta), and aluminum (Al). In some embodiments, the bottommost and/or topmost layer of the insulating reflector 41 includes a material different from that of an intermediate layer located therebetween and/or has a thickness different from that of the intermediate layer and/or is formed by a method different from that of the intermediate layer. The bottommost layer of the insulating reflector 41 is in direct contact with the insulating layer 42, and the topmost layer of the insulating reflector 41 is in direct contact with the adhesive layer 51 or the insulating structure 60.

In some embodiments, the insulating layer 42 may include the same material as the plurality of first sublayers of the insulating reflector 41. For example, when the insulating reflector 41 is formed as a distributed Bragg reflector including SiO₂/TiO₂ or SiO₂/Nb₂O₅, the insulating layer 42 may be formed of SiO₂. Although the insulating layer 42 is formed of the same material as at least part of the insulating reflector 41, it is not required to have a high film quality as a DBR insulating film. The insulating reflector 41 and the insulating layer 42 may be formed by different methods. The interface between the insulating layer 42 and the insulating reflector 41 can be distinguished in visual (e.g., in SEM or TEM images). In some embodiments, a total thickness of the plurality of first sublayers of the insulating reflector 41 is smaller than a total thickness of the insulating layer 42.

As shown in FIGS. 2, 5A, and 6A, the insulating structure 60 continuously covers all exposed surfaces of the metal reflective structure 52 and the adhesive layer 51 to protect the adhesive layer 51 and the metal reflective structure 52. For example, an upper surface and a side surface of the metal reflective structure 52 and the adhesive layer 51 may be protected by the insulating structure 60. The metal reflective structure 52 and the adhesive layer 51 may be encapsulated between the insulating structure 60 and the insulating reflective structure 40. In some embodiments, by forming the insulating structure 60, deterioration of reflectivity of the metal reflective structure 52 due to subsequent processes can be avoided, and migration of metal elements included in the metal reflective structure 52 can be suppressed.

In some embodiments, as shown in FIG. 1, the second insulating structure openings 602 are disposed offset from the plurality of insulating reflective structure openings 402, in other words, the second insulating structure openings 602 do not overlap the plurality of insulating reflective structure openings 402. To maintain a pattern in which the plurality of insulating reflective structure openings 402 are arranged at equal spacing, in a top view of the optoelectronic device 1, one or a plurality of second insulating structure openings 602 are respectively located at any position within a polygon region defined by the arrangement of the plurality of insulating reflective structure openings 402. In some embodiments, the polygonal arrangement formed by the plurality of insulating reflective structure openings 402 includes triangular, quadrilateral (e.g., rectangular), pentagonal, or hexagonal arrangements.

In some embodiments, there is only one second insulating structure opening 602 in any one of the polygons formed by the plurality of insulating reflective structure openings 402.

In this embodiment, the second insulating structure opening 602 has a width not greater than a width of the second insulating reflective structure opening 4022, the fourth insulating reflective structure opening 4024, or the fifth insulating reflective structure opening 4025.

As shown in FIG. 1, one or a plurality of second insulating structure openings 602 are located within a region of a projection area of the second electrode pad 92. The plurality of second insulating structure openings 602 may be covered by the second extension electrode 72. As shown in FIG. 1, the plurality of second insulating structure openings 602 may overlap the second protecting structure openings 802, and may be disposed at equal or unequal spacing between the second electrode pad 92 and the second extension electrode 72. In other embodiments, besides a circular shape as shown in FIG. 1, the pattern of the second insulating structure openings 602 may be varied to a rectangular, triangular, or regular or irregular polygonal shape.

In some embodiments, as shown in FIG. 1, the plurality of second insulating structure openings 602 have the same width or diameter. In other embodiments (not shown), the plurality of second insulating structure openings 602 may have different widths or diameters.

As shown in FIGS. 5A and 6A, the first extension electrode 71 may be disposed on the insulating structure 60. The first extension electrode 71 further extends through the first insulating structure openings 601 to the first semiconductor structure 21 at the first contact first portion CT1 and the first contact second portion CT1′, thereby electrically connecting to the first semiconductor structure 21.

As shown in FIG. 2, the second extension electrode 72 may be disposed on the insulating structure 60. The second extension electrode 72 extends through the second insulating structure openings 602 to contact the metal reflective structure 52, thereby electrically connecting to the second semiconductor structure 23.

The first extension electrode 71 and the second extension electrode 72 are disposed offset from each other, and the location of the second extension electrode 72 is selected to avoid the through holes 200, thereby rendering the upper surfaces of the second extension electrode 72 and the second electrode pad 92 more planar, or substantially planarized.

In some embodiments, the first extension electrode 71 and the second extension electrode 72 may be disposed on the insulating structure 60 and formed of different materials. For example, the first extension electrode 71 and the second extension electrode 72 may be formed of materials including at least one of aluminum (Al), gold (Au), tungsten (W), platinum (Pt), iridium (Ir), silver (Ag), copper (Cu), nickel (Ni), titanium (Ti), chromium (Cr), and alloys thereof.

The protecting structure 80 includes a first protecting structure opening 801 located on the first extension electrode 71 and a second protecting structure opening 802 located on the second extension electrode 72. The first protecting structure openings 801 may expose the first extension electrode 71, and the second protecting structure openings 802 may expose the second extension electrode 72.

Referring to FIG. 1, in a top view, projections of the first electrode pad 91 and the second electrode pad 92 do not overlap a projection of the through holes 200, thereby planarizing the surface of the optoelectronic device 1 and contributing an increased bonding area between a package substrate and the first electrode pad 91 and the second electrode pad 92 during a subsequent packaging process. Referring to FIG. 1, the plurality of first insulating structure openings 601 are located in a region outside a projection area of the first electrode pad 91 and are covered by the first extension electrode 71.

The first electrode pad 91 may be disposed on the first extension electrode 71 through the first protecting structure openings 801, and the second electrode pad 92 may be disposed on the second extension electrode 72 through the second protecting structure openings 802. A first solder pad (not shown) may be disposed on the first electrode pad 91, and a second solder pad (not shown) may be disposed on the second electrode pad 92. The first solder pad and the second solder pad may be formed of conductive materials (e.g., Sn or AuSn). As shown in FIG. 1, in a top view, the first electrode pad 91 may be adjacent to the first side 11, and the second electrode pad 92 may be adjacent to the second side 12.

The first electrode pad 91 and the second electrode pad 92 include metallic materials such as chromium (Cr), titanium (Ti), tungsten (W), gold (Au), aluminum (Al), indium (In), tin (Sn), nickel (Ni), platinum (Pt), silver (Ag), or alloys thereof. The first electrode pad 91 and the second electrode pad 92 may each be formed of a single layer or multiple layers. For example, the first electrode pad 91 or the second electrode pad 92 may include a Ti/Au layer, a Ti/Pt/Au layer, a Cr/Au layer, a Cr/Pt/Au layer, a Ni/Au layer, a Ni/Pt/Au layer, a Cr/Al/Cr/Ni/Au layer, or an Ag/NiTi/TiW/Pt layer. The first electrode pad 91 and the second electrode pad 92 may provide a current path from an external power source to the first semiconductor structure 21 and the second semiconductor structure 23. In some embodiments, each of the first electrode pad 91 and the second electrode pad 92 has a thickness between 0.5 μm and 5 μm.

In some embodiments, the insulating structure 60 and the protecting structure 80 are disposed on the semiconductor stack 20 and serve as protective films of the optoelectronic device 1 and interlayer insulating films for electrostatic protection. In some embodiments, as insulating films, the insulating structure 60 and the protecting structure 80 may be single-layer structures including metal oxides or metal nitrides, for example, at least one oxide or nitride selected from the group consisting of silicon (Si), titanium (Ti), zirconium (Zr), niobium (Nb), tantalum (Ta), and aluminum (Al). In other embodiments, the insulating structure 60 and the protecting structure 80 include two or more materials of different refractive indices alternately stacked to form a distributed Bragg reflector (DBR) structure that selectively reflects light of specific wavelengths. For example, a high-reflectance reflective structure may be formed by stacking two or three insulating layers of materials such as SiO₂, TiO₂, Nb₂O₅, or Al₂O₃. When a DBR structure is formed by stacking sublayers such as SiO₂/TiO₂ or SiO₂/Nb₂O₅, each sublayer of the DBR structure is designed to have an optical thickness equal to one or integer multiple of a quarter wavelength (λ/4) of the light emitted by the active structure 22. The optical thickness of each sublayer of the DBR structure may have a deviation of ±30%. Since reflectivity may be affected by changing the optical thickness of each sublayer of the DBR structure, each physical thickness of the sublayers in the insulating structure 60 and the protecting structure 80 obtained based on the optical thickness of the DBR structure may be formed by e-beam evaporation to stably control the thickness of each sublayer in the insulating structure 60 and the protecting structure 80.

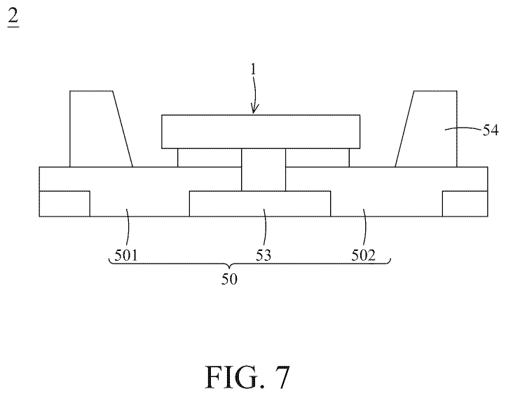

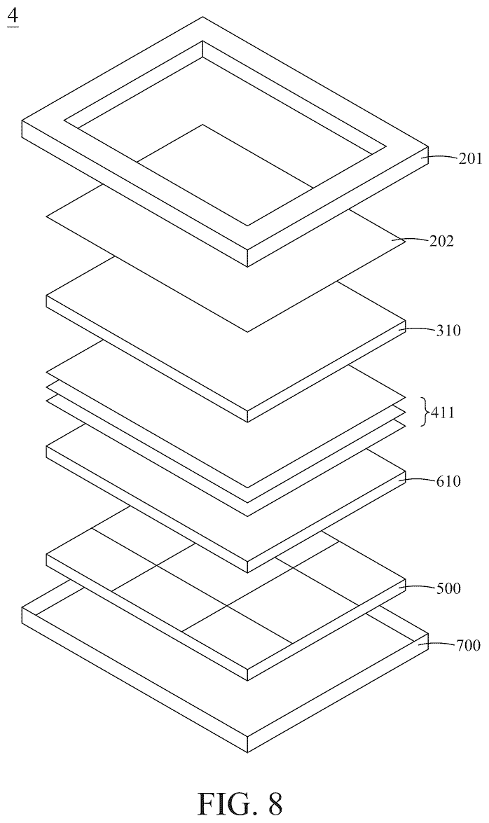

FIG. 7 is a schematic diagram of a light-emitting device 2 according to some embodiments of the present disclosure. One of the optoelectronic devices 1 in the foregoing embodiments is mounted in the form of a flip chip on a first spacer 501 and a second spacer 502 of a package substrate 50. The first spacer 501 and the second spacer 502 are electrically insulated by an insulation portion 53 including an insulating material. In a flip-chip mounting configuration, a growth substrate side or the first semiconductor structure 21 side opposite to a surface where the electrode pads are formed is set as a main light-emitting surface, for example, a light-emitting surface 10t of the carrier substrate 10 or a light-emitting surface 2S of the first semiconductor structure 21 serving as the main light-emitting surface of the optoelectronic device 1. To increase the light extraction efficiency of the light-emitting device 2, a reflective structure 54 may be disposed around the optoelectronic device 1.

FIG. 8 is a schematic diagram of a backlight module 4 according to some embodiments of the present disclosure. The backlight module 4 includes a first frame 201, a liquid crystal display panel 202, a brightness enhancement film 310, an optical module 411, a light-emitting module assembly 500, and a second frame 700. The light-emitting module assembly 500 includes a plurality of the optoelectronic devices 1 of the foregoing embodiments or the light-emitting devices 2. The optoelectronic devices 1 are arranged in an edge-type or direct-type light-emitting configuration in the light-emitting module assembly 500. In some embodiments, the backlight module 4 further includes a wavelength conversion structure 610 disposed on the light-emitting module assembly 500.

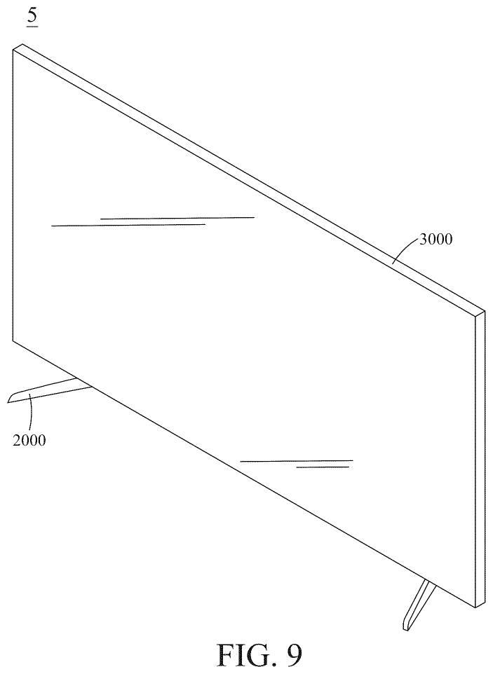

FIG. 9 is a schematic diagram of a display 5 according to some embodiments of the present disclosure. The display 5 includes an LED light-emitting panel 3000 and a current source (not shown). A bracket 2000 is used to support the LED light-emitting panel 3000. The LED light-emitting panel 3000 includes a plurality of the optoelectronic devices 1 or the light-emitting devices 2 described in the foregoing embodiments, or the backlight module 4. In some embodiments, the LED light-emitting panel 3000 includes a plurality of pixel units. Each pixel unit includes a plurality of the optoelectronic devices 1 or the light-emitting devices 2 described in the foregoing embodiments to emit different colors, for example, each pixel unit includes three optoelectronic devices 1 or light-emitting devices 2 that respectively emit red, green, and blue light.

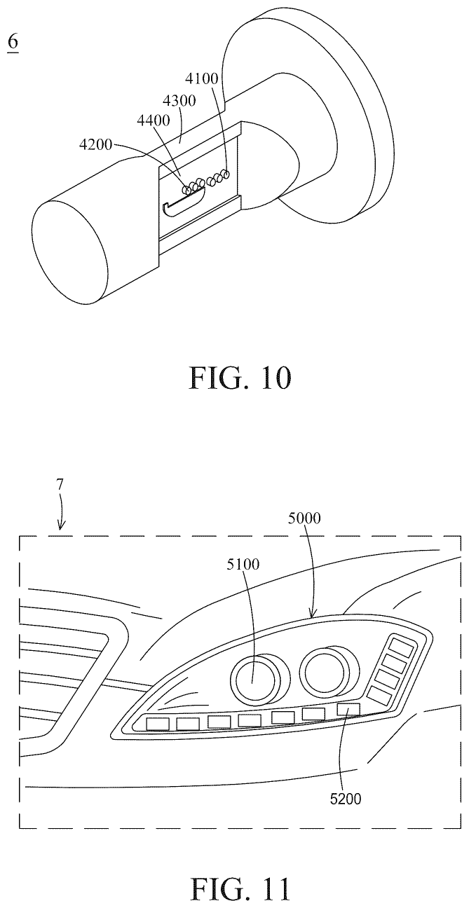

FIG. 10 is a schematic diagram of a light-emitting device 6 according to some embodiments of the present disclosure. In some embodiments, the light-emitting device 6 is an LED bulb for automobiles that can be plug-fixed into a mounting through hole in a rear housing of an automotive headlamp assembly. The light-emitting device 6 includes a first LED chip 4100 for low-beam emission or a second LED chip 4200 for high-beam emission, an elongated columnar light column 4300, a driving power circuit board 4400, heat-dissipating fins (not shown), a fan for heat dissipation (not shown), a fan cover for shielding the fan (not shown), a power line (not shown) for electrical connection to a vehicle battery, and a plug (not shown) provided at an end of the power line. The first LED chip 4100 or the second LED chip 4200 in the light-emitting device 6 may include any one or more of the foregoing optoelectronic devices 1 or light-emitting devices 2.

FIG. 11 is a schematic diagram of a light-emitting device 7 according to some embodiments of the present disclosure. In some embodiments, the light-emitting device 7 may be an automotive lighting lamp 5000 and can be applied to daytime running lights, headlights, taillights, or turn signals. A main lighting lamp 5100 in the automotive lighting lamp 5000 may be a main light source. For example, when the automotive lighting lamp 5000 is used as a headlamp, the main lighting lamp 5100 can function to illuminate the front of a vehicle. A combination lamp 5200 may have at least two functions. For example, when the automotive lighting lamp is used as a headlamp, the combination lamp 5200 can perform functions of a daytime running light (DRL) and a turn signal. The main lighting lamp 5100 or the combination lamp 5200 may include any one or more of the foregoing optoelectronic devices 1 or light-emitting devices 2.

The components in the above embodiments are described so that those of ordinary skill in the art to which the present disclosure pertains may more fully understand viewpoints of the embodiments of the present disclosure. Those of ordinary skill in the art should understand that, based on the embodiments of the present disclosure, other processes and structures may be designed or modified to achieve the same objectives and/or advantages as those of the embodiments described herein. Those of ordinary skill in the art should also understand that such equivalent structures do not depart from the spirit and scope of the present disclosure, and that various changes, alternatives, and substitutions may be made without departing from the spirit and scope of the present disclosure. Accordingly, the scope of protection of the present disclosure shall be defined by the claims appended hereto. In addition, although the present disclosure has been described with several preferred embodiments as above, it is not intended to limit the present disclosure.

References to features, advantages, or similar language throughout the specification are not intended to imply that all features and advantages that may be realized with the present disclosure must or can be achieved in any single embodiment of the present disclosure. Rather, language regarding features and advantages is understood to mean that specific features, advantages, or characteristics described in connection with the embodiments are included in at least one embodiment of the present disclosure. Therefore, discussions of features and advantages and similar language throughout the specification may, but do not necessarily, refer to the same embodiment.

Furthermore, in one or more embodiments, any appropriate combination of the features, advantages, and characteristics described in the present disclosure may be implemented. Based on the description herein, those skilled in the relevant art will recognize that the present disclosure may be implemented without one or more specific features or advantages of a particular embodiment. In other cases, additional features and advantages may be identified in certain embodiments that may not be present in all embodiments of the present disclosure.

1. An optoelectronic device comprising:
a first semiconductor structure;
a semiconductor mesa disposed on the first semiconductor structure and comprising an active structure and a second semiconductor structure, the semiconductor mesa comprising a first boundary with a length; and
an insulating reflective structure comprising a first insulating reflective structure opening disposed on the second semiconductor structure;
wherein in a top view of the optoelectronic device, the insulating reflective structure opening comprises an annular opening disposed along the first boundary of the semiconductor mesa.

2. The optoelectronic device according to claim 1, further comprising:
a first recessed region exposing the first semiconductor structure and surrounding the semiconductor mesa; and wherein the insulating reflective structure opening further comprises a plurality of second insulating reflective structure openings, and the first insulating reflective structure opening is closer to the first recessed region than the plurality of second insulating reflective structure openings

3. The optoelectronic device according to claim 2, further comprising a second recessed region surrounded by the semiconductor mesa and exposing the first semiconductor structure, wherein the semiconductor mesa further comprises a second boundary between the second recessed region and the first recessed region.

4. The optoelectronic device according to claim 2, wherein the first insulating reflective structure opening comprises a top-view area greater than that of each of the plurality of second insulating reflective structure openings.

5. The optoelectronic device according to claim 1, wherein the first insulating reflective structure opening has a first length along the first boundary, and a ratio between the first length and the length of the first boundary is greater than 0.8.

6. The optoelectronic device according to claim 3, wherein the insulating reflective structure opening further comprises a third insulating reflective structure opening disposed along the second boundary.

7. The optoelectronic device according to claim 6, wherein the third insulating reflective structure opening comprises an annular opening.

8. The optoelectronic device according to claim 3, wherein the insulating reflective structure opening further comprises a plurality of fourth insulating reflective structure openings disposed along the second boundary.

9. The optoelectronic device according to claim 8, wherein the plurality of fourth insulating reflective structure openings is arranged in an annular pattern.

10. The optoelectronic device according to claim 8, wherein the third insulating reflective structure opening is closer to the second recessed region than the plurality of fourth insulating reflective structure openings.

11. The optoelectronic device according to claim 2, wherein the insulating reflective structure opening further comprises a fifth insulating reflective structure opening disposed along the first boundary.

12. The optoelectronic device according to claim 11, wherein the first insulating reflective structure opening is closer to the first boundary of the semiconductor mesa than the fifth insulating reflective structure opening.

13. The optoelectronic device according to claim 11, further comprising a first contact first portion is formed in the first recessed region.

14. The optoelectronic device according to claim 13, further comprising a first extension electrode disposed on the first recessed region to define the first contact first portion thereat.

15. The optoelectronic device according to claim 14, wherein in the top view, the fifth insulating reflective structure opening is not intersected by a line orthogonal to a side of the optoelectronic device and passing through the first contact first portion.

16. The optoelectronic device according to claim 13, further comprising a second extension electrode disposed on the semiconductor mesa and electrically connected to the second semiconductor structure.

17. The optoelectronic device according to claim 16, further comprising an insulating structure disposed on the semiconductor mesa, and the first extension electrode and the second extension electrode are disposed on the insulating structure.

18. The optoelectronic device according to claim 1, further comprising a metal reflective structure disposed on the insulating reflective structure and filled into the insulating reflective structure opening.

19. The optoelectronic device according to claim 18, further comprising an adhesive layer disposed between the metal reflective structure and the insulating reflective structure and filled into the insulating reflective structure opening.

20. The optoelectronic device according to claim 19, wherein the adhesive layer comprises an adhesive layer opening overlapping the insulating reflective structure opening, and the metal reflective structure is filled into the adhesive layer opening.
